(19) United States
(12) Patent Application Publication
(10) Pub. No.: US 2016/0062251 A1
(43) Pub. Date: Mar. 3, 2016

(54) CLEANING APPARATUS OF OPTICAL APPARATUS, OPTICAL APPARATUS, AND EXPOSURE APPARATUS

(71) Applicant: Kabushiki Kaisha Toshiba, Minato-ku (JP)

(72) Inventor: Munetaka MACHIDA, Kuwana (JP)

(73) Assignee: Kabushiki Kaisha Toshiba, Minato-ku (JP)

(21) Appl. No.: 14/587,413

(22) Filed: Dec. 31, 2014

Related U.S. Application Data
(60) Provisional application No. 62/042,318, filed on Aug. 27, 2014.

(51) Int. Cl. G03F 7/20; G02B 27/00

(52) U.S. Cl. CPC G03F 7/70883; G02B 27/0006

(57) ABSTRACT

According to one embodiment, there is provided a cleaning apparatus of an optical apparatus including a first medium spraying unit. The first medium spraying unit sprays a medium on an adhered substance adhered to an optical component. The medium is cooled to a temperature lower than a room temperature and changes a state of the adhered substance into a fragile state.

### CROSS-REFERENCE TO RELATED APPLICATIONS

This application is based upon and claims the benefit of priority from U.S. Provisional Application No. 62/042,318, filed on Aug. 27, 2014; the entire contents of which are incorporated herein by reference.

### FIELD

Embodiments described herein relate generally to a cleaning apparatus of an optical apparatus, an optical apparatus, and an exposure apparatus.

### BACKGROUND

In an extreme ultraviolet (EUV) exposure apparatus, Sn is excited by a CO₂ laser and the like, and an extreme ultraviolet light (EUV light) generated as a result is used as a light source. When excited, Sn particles scatter and adhere to a surface of an optical system such as a collector mirror. In the optical system to which the Sn particles are adhered, the EUV light is subjected to dispersion. Accordingly, guiding of the EUV light to an originally-expected optical path becomes impossible. As a result, a decrease in density or in accuracy of energy reaching the EUV exposure apparatus is caused.

### BRIEF DESCRIPTION OF THE DRAWINGS

FIG. 1 is a view schematically illustrating a schematic configuration of an EUV exposure apparatus;

FIG. 2 is a view illustrating one example of a configuration of a light source according to a first embodiment;

FIG. 3 is a view schematically illustrating one example of a configuration of a discharged produced plasma (DPP) system EUV light generation unit;

FIGS. 4A to 4E are views schematically illustrating one example of a procedure of a cleaning method of the light source according to the first embodiment;

FIG. 5 is a flowchart illustrating one example of a procedure of cleaning processing for each point according to the first embodiment;

FIG. 6 is a view illustrating one example of a configuration of a light source according a second embodiment;

FIGS. 7A to 7E are views schematically illustrating one example of a procedure of a cleaning method of the light source according to the second embodiment; and

FIG. 8 is a view illustrating one example of a configuration of a light source according to a third embodiment.

### DETAILED DESCRIPTION

In general, according to one embodiment, there is provided a cleaning apparatus of an optical apparatus including a first medium spraying unit. The first medium spraying unit sprays a medium on an adhered substance adhered to an optical component. The medium is cooled to a temperature lower than a room temperature and changes a state of the adhered substance into a fragile state.

The cleaning apparatus, an exposure apparatus, and a cleaning method according to the embodiment are described below in detail with reference to the accompanying drawings. Note, however, that the present invention is not to be limited to the following embodiments.

### First Embodiment

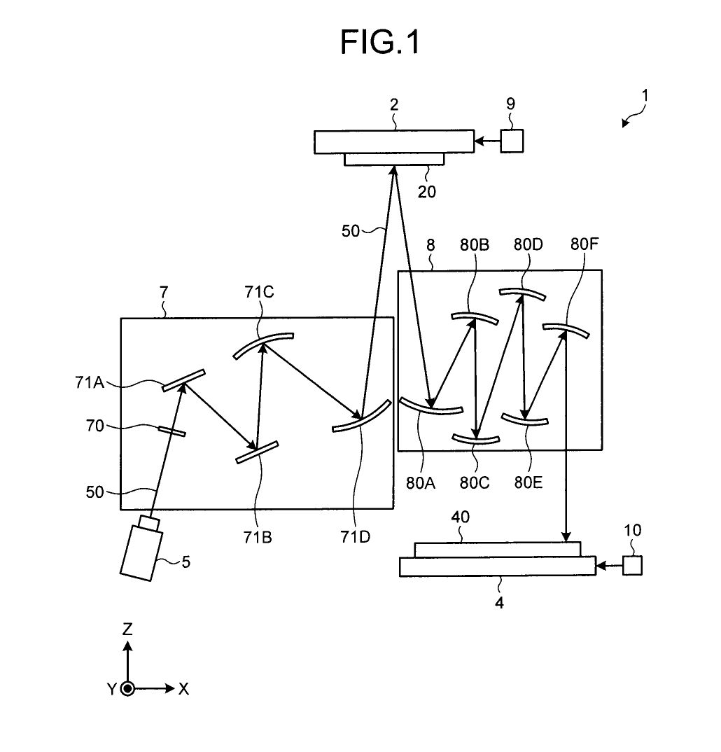

FIG. 1 is a view schematically illustrating a schematic configuration of an EUV exposure apparatus. In this view, an X direction, a Y direction, and a Z direction are illustrated as directions orthogonal to each other. An EUV exposure apparatus 1 includes a mask stage 2 and a wafer stage 4. The mask stage 2 fixes a reflective mask 20 by an electrostatic adsorption mechanism, for example. The mask stage 2 is configured to be movable in the X direction and the Y direction. The X direction and the Y direction are directions parallel to a mask placement surface of the mask stage 2. To the mask stage 2, a mask stage drive unit 9 configured to move the reflective mask 20 in the X direction and the Y direction is connected.

The reflective mask 20 has a structure mainly constituted of a multi-layer film, which is placed on a substrate, to which surface processing having a high-low difference of reflectance is implemented. The substrate is constituted of quartz glass and the like. The multi-layer film is constituted of thin films, each having a different index of refraction, layered alternately on the substrate. EUV light is reflected in this configuration. As the multi-layer film, for example, Mo/Si, Mo/Be, and the like may be used.

On the wafer stage 4, a wafer 40, on which a resist is applied, is placed. The wafer stage 4 fixes the wafer 40 by the electrostatic adsorption mechanism, for example. The wafer stage 4 is configured to be movable in the X direction, the Y direction, and the Z direction. The X direction and the Y direction are directions parallel to a placement surface of the wafer 40 of the wafer stage 4. To the wafer stage 4, a wafer stage drive unit 10 configured to move the wafer 40 in the X direction, the Y direction, and the Z direction is connected.

Furthermore, the EUV exposure apparatus 1 has a light source 5, an illumination optical system 7, and a projection optical system 8. The light source 5 emits the EUV light as exposure light 50. A detailed structure of the light source 5 is described below.

The illumination optical system 7 irradiates the reflective mask 20 with the exposure light 50 from the light source 5. The illumination optical system 7 has a plurality of mirrors 71A to 71D configured to guide the exposure light 50 from the light source 5 to the reflective mask 20. Note that a filter 70 may also be installed as illustrated in a case where the exposure light 50 emitted from the light source 5 includes a wavelength other than a predetermined wavelength bandwidth (for example, from 5 to 20 nm), which includes a wavelength (13.5 nm).

The projection optical system 8 projects the exposure light 50 reflected by the reflective mask 20 to the mask stage 2. The projection optical system 8 has a plurality of mirrors 80A to 80F.

Note that as described above, the exposure light 50 is the EUV light of the wavelength of 5 to 20 nm, for example. The EUV light has a characteristic of being scattered by colliding into an atmospheric molecule in an air atmosphere. Therefore, at least the light source 5, the illumination optical system 7, the reflective mask 20, the projection optical system 8, and the wafer 40 are arranged in a vacuum atmosphere.

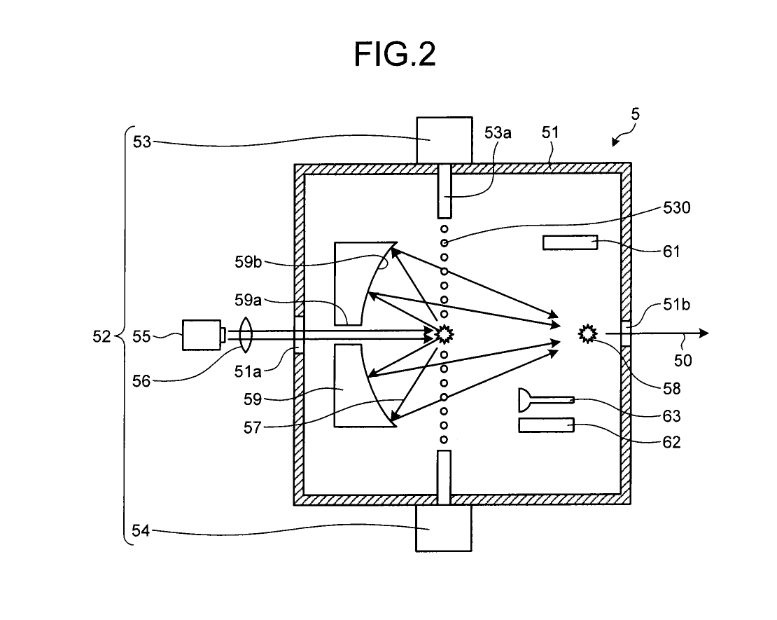

FIG. 2 is a view illustrating one example of a configuration of the light source according to the first embodiment. The light source 5 is provided with an EUV light generation unit 52 and a collector mirror 59 inside a vacuum chamber 51. Inside of the vacuum chamber 51 is evacuated by a vacuum pump, which is not illustrated, so as to be a predetermined degree of vacuum.

In a case where it is a laser produced plasma (LPP) system, the EUV light generation unit 52 is provided with a liquid droplet supply unit 53, a liquid droplet receiving unit 54, a laser oscillator 55, and a condenser lens 56. The liquid droplet supply unit 53 is provided in the vacuum chamber 51 and supplies a Sn droplet 530 (liquid droplet) to the inside of the vacuum chamber 51 through a nozzle 53a. The Sn droplet 530 is supplied in a mist form. Furthermore, the Sn droplet 530 has a size of about 30 for example. The liquid droplet receiving unit 54 is provided in the vacuum chamber 51 so as to oppose an arrangement position of the liquid droplet supply unit 53. It gathers the Sn droplet 530 supplied from the liquid droplet supply unit 53. The laser oscillator 55 outputs a pulse laser for exciting the Sn. As the laser oscillator 55, for example, a CO₂ laser oscillator may be used. A laser beam output from the laser oscillator 55 is condensed by the condenser lens 56 on the Sn droplet 530 supplied from the liquid droplet supply unit 53. That is, the EUV light generation unit 52 is configured such that the Sn droplet 530 supplied from the liquid droplet supply unit 53 is irradiated with the laser from the laser oscillator 55. The Sn droplet 530, which has been irradiated with the laser, is excited and emits EUV light 57.

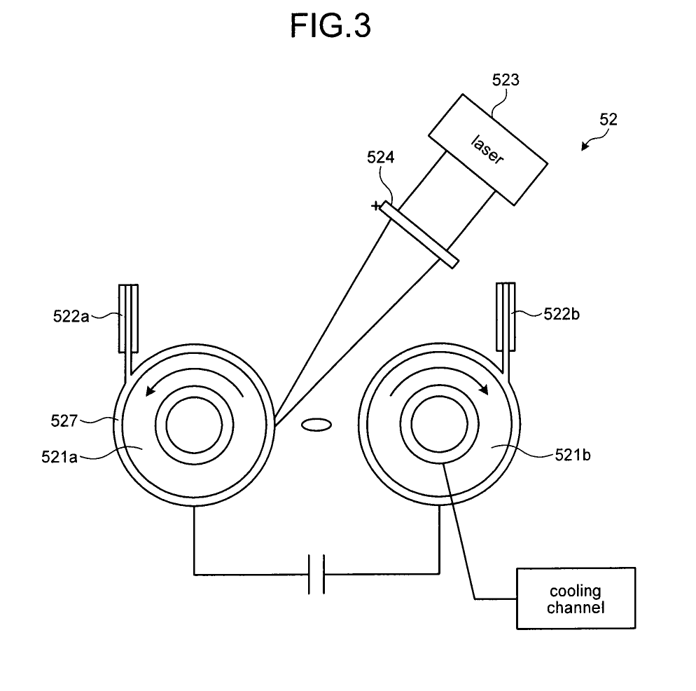

In FIG. 2, the LPP system EUV light generation unit 52 is illustrated; however, it is also possible to use the DPP system EUV light generation unit 52. FIG. 3 is a view schematically illustrating one example of a configuration of the DPP system EUV light generation unit. The EUV light generation unit 52 includes two rotation electrodes 521a and 521b, Sn supply sources 522a and 522b, a laser oscillator 523, and a condenser lens 524. The Sn supply sources 522a and 522b supply liquid Sn to a surface of each of the rotation electrodes 521a and 521b. Accordingly, a Sn thin film 527 is formed on each of the surfaces of the two rotation electrodes 521a and 521b. It is irradiated with a laser from the laser oscillator 523, whereby a plasma arc is caused between the two rotation electrodes 521a and 521b and the EUV light is generated. Note that, in the example explained above, Sn is used in the generation of the EUV light. However, other metal may be used.

The collector mirror 59 condenses the EUV light 57 generated in the EUV light generation unit 52 on a position of a secondary light source 58. On an inner surface of the collector mirror 59, there is formed a multi-layer film coat 59b, which reflects the EUV light 57. Similar to the reflective mask 20, this multi-layer film coat 59b is constituted of, for example, Mo/Si, Mo/Be, and the like. The EUV light 57, which has been condensed on the position of the secondary light source 58, is emitted to the illumination optical system 7 as the exposure light 50 through a window 51b, which is provided in the vacuum chamber 51. Note that the collector mirror 59 is provided with a hole 59a through which the laser beam from the laser oscillator 55 is allowed to pass. Corresponding to this, the vacuum chamber 51 is provided with a window 51a through which the laser beam is allowed to pass. During exposure processing, the Sn scattered when the EUV light is generated is adhered to a surface of the collector mirror 59.

The light source 5 is further provided with a surface condition detection unit 61, a low temperature medium spraying unit 62, and a gathering unit 63 inside the vacuum chamber 51. The surface condition detection unit 61 detects a surface condition of the collector mirror 59. The surface condition detection unit 61, for example, determines the time to perform cleaning of the collector mirror 59 and the time to end the cleaning during the cleaning. As a method of detecting a surface condition of the collector mirror 59, there is a method, for example, in which reflectance of the collector mirror 59 is measured and the reflectance is used for determining. In a case where the reflectance is worsened to a first threshold value or more, it is determined that it is the time to perform the cleaning. In a case where of the reflectance is improved to a second threshold value or above, it is determined that it is the time to end the cleaning. Furthermore, as one example of the method of detecting the surface condition of the collector mirror 59, there is a method of measuring film thickness of the Sn by using a laser interferometer.

Note that in a case where a material adhered to the surface of the collector mirror 59 is, for example, a material capable of developing an anisotropic crystal growth, an amount of adhesion to the surface of the collector mirror 59 becomes locally different. In this case, it is possible to assume the amount of adhesion if information such as flatness is obtained by measuring scattered light by laser radiation. Furthermore, in a case where the collector mirror 59 is conductive and where the adhered substance has a dielectric constant different from a dielectric constant of an atmosphere inside the vacuum chamber 51, it is possible to provide a portable counter electrode on a surface side of the collector mirror 59. That is, the portable counter electrode is provided in the collector mirror 59 so as to realize a capacitor-like arrangement. In this configuration as well, it is possible to assume the amount of adhesion from a change in the dielectric constant. As above, the surface condition detection unit 61 may detect not only the film thickness of the adhered substance such as the Sn but also whether the adhered substance is adhered to the collector mirror 59 or not as well as the amount of adhesion thereto.

The low temperature medium spraying unit 62 sprays a low temperature medium on the surface of the collector mirror 59. As the low temperature medium, it is possible to use a sublimable solid material having a temperature lower than a phase transition temperature of the Sn. As this material, dry ice may be used, for example. The Sn adhered to the surface of the collector mirror 59 has a crystal structure of a tetragonal system called βSn. The low temperature medium from the low temperature medium spraying unit 62 is sprayed on the βSn, and when it reaches a temperature of 13.2 degrees or below, phase transition from the βSn to αSn having a diamond structure takes place. The αSn has a fragile characteristic. That is, it is possible to cause the phase transition of the Sn to the αSn having the fragile characteristic by spraying a low temperature solid medium having a temperature lower than the phase transition temperature of the Sn on the surface of the collector mirror 59. Furthermore, by continuing to spray the low temperature solid medium in that state, the αSn, which has become fragile, peels off from the surface of the solid. Note that in a case where the Sn contains impurity, the phase transition takes place at −10° C. or below, whereby the low temperature solid medium having a temperature sufficiently lower than −10° C., for example, may be used. In this case, the dry ice may be used as the low temperature solid medium. Furthermore, the solid material that has dropped inside the vacuum chamber 51 is later vaporized and is evacuated without contaminating the inside of the vacuum chamber 51.

Note that, the temperature of the low temperature medium to be sprayed is within a temperature range in which thermal distortion, which is caused by spraying the low temperature medium, of the collector mirror 59 causes elastic deformation of the collector mirror 59 (hereinafter, referred to as “within an elastic deformation region”). That is, the temperature is in the temperature range in which the collector mirror 59 is not permanently deformed by the thermal distortion due to cooling. In a case where the temperature is not within the elastic deformation region of the collector mirror 59, an optical performance of the collector mirror 59 is reduced due to the thermal distortion caused to the collector mirror 59. As a result, it is not possible to obtain a desired EUV light performance. Therefore, the temperature of the low temperature medium is to be within the temperature range in which the thermal distortion of the collector mirror 59 is within the elastic deformation region.

The gathering unit 63 gathers the Sn containing the αSn, which is desorbed from the collector mirror 59 by the low temperature medium spraying unit 62. For example, the gathering unit 63 gathers the Sn, which has been desorbed by sucking. In this case, it sucks with pressure even lower than pressure in the vacuum chamber.

In a case where the EUV exposure apparatus 1 is in an operating state, the surface condition detection unit 61, the low temperature medium spraying unit 62, and the gathering unit 63 are arranged inside of the vacuum chamber 51 in a range having no influence on generation of the EUV light 57. Specifically, it is arranged outside of a region connecting the secondary light source 58 with a peripheral portion of the collector mirror 59. This position is hereinafter referred to as a storage position. Then, when performing cleaning processing, it is moved near the surface of the collector mirror 59. This position is hereinafter referred to as an operating position. Furthermore, it is desirable that the gathering unit 63 be arranged close to the low temperature medium spraying unit 62 during the cleaning processing.

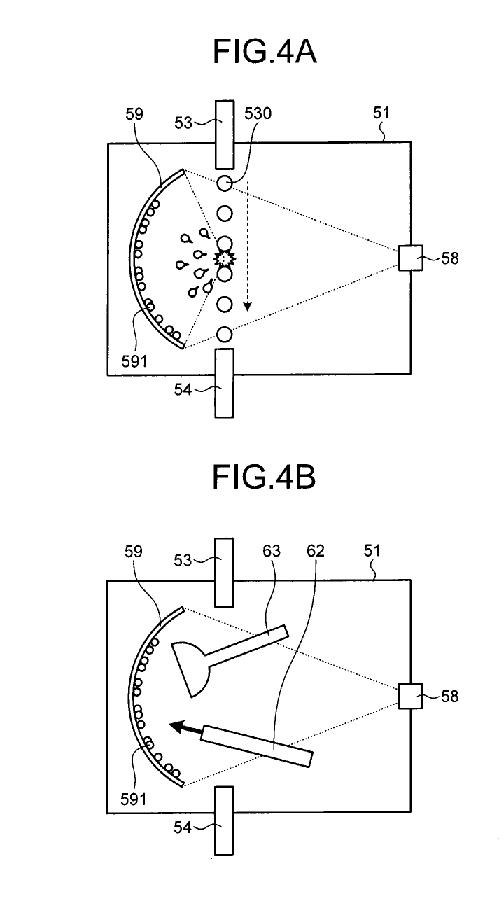

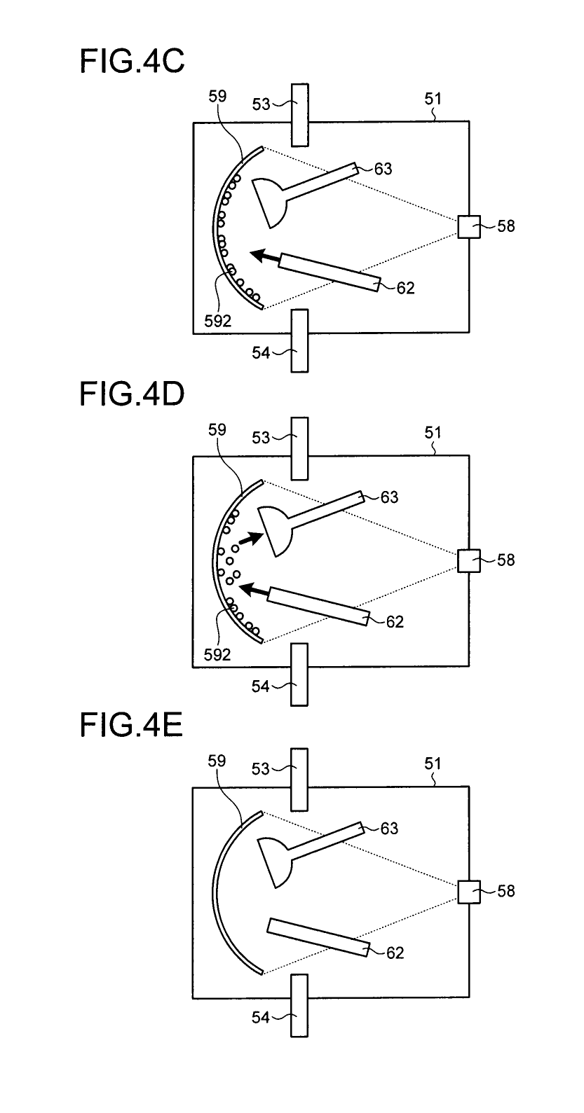

Next, the cleaning processing of the light source of this configuration is described herein. FIGS. 4A to 4E are views schematically illustrating one example of a procedure of a cleaning method of the light source according to the first embodiment. For example, as illustrated in FIG. 4A, βSn 591, which is stable at a normal temperature, is deposited on the surface of the collector mirror 59 during the exposure processing. Then, it is determined by the surface condition detection unit 61 that cleaning of the collector mirror 59 is necessary. Thereupon, the cleaning processing of the light source 5 is executed. As illustrated in FIG. 4B, the low temperature medium spraying unit 62 and the gathering unit 63 are moved from the storage position to the operating position by a moving mechanism, which is not illustrated. Then, in this state, the low temperature solid medium is sprayed on the surface of the collector mirror 59. Due to spraying of the low temperature solid medium, a temperature of the βSn 591 is decreased, and it is cooled to the phase transition temperature or below. Accordingly, as illustrated in FIG. 4C, phase transition to αSn 592 having a fragile characteristic takes place.

Thereafter, as illustrated in FIG. 4D, the low temperature solid medium is continued to be sprayed on the surface of the collector mirror 59. By shock caused by the low temperature solid medium colliding into the collector mirror 59, the αSn, which has become fragile, is desorbed. Then, the desorbed αSn is gathered by the gathering unit 63. Note that the spraying of the low temperature medium by the low temperature medium spraying unit 62 is performed on an entire surface of the collector mirror 59.

Next, as illustrated in FIG. 4E, when the αSn 592 on the surface of the collector mirror 59 is removed, an end point of the cleaning is detected by the surface condition detection unit 61. Then, the low temperature medium spraying unit 62 and the gathering unit 63 are moved from the operating position to the storage position. Subsequently, evacuation is performed until the low temperature solid medium, which has dropped to a bottom of the vacuum chamber 51 during the cleaning, sublimates and the inside of the vacuum chamber 51 reaches a predetermined pressure.

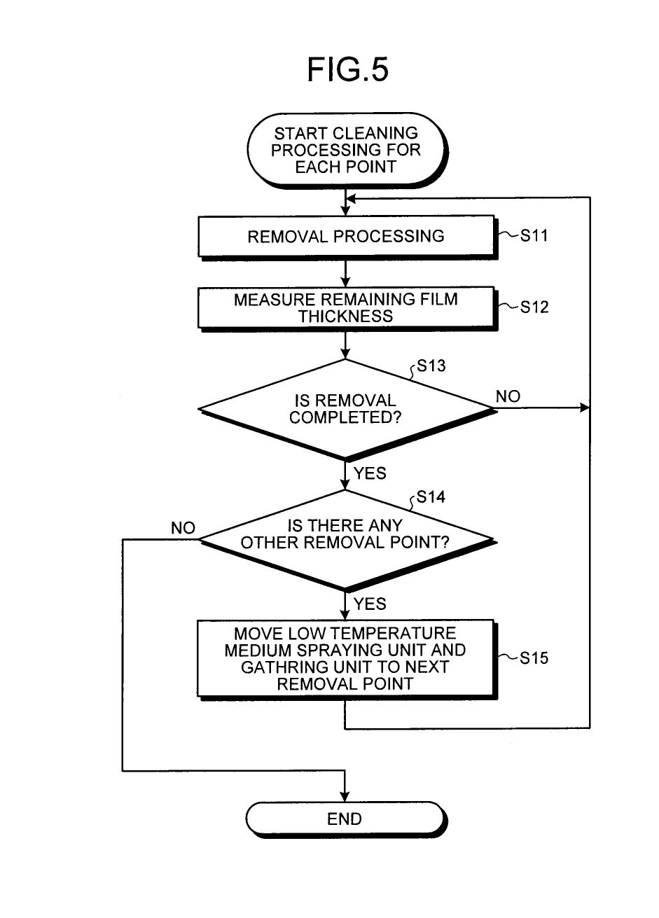

Note that the cleaning may be performed on the entire surface of the collector mirror 59 simultaneously or may be performed for each point. A case where the cleaning processing is performed for each point is described herein. FIG. 5 is a flowchart illustrating one example of a procedure of the cleaning processing for each point according to the first embodiment.

First, at a first removal point, removal processing as illustrated in FIGS. 4A to 4E is executed (step S11). Next, remaining film thickness of the Sn at this removal point is measured by the surface condition detection unit 61 (step S12). Subsequently, by using the remaining film thickness, it is determined whether removal for this removal point is completed or not (step S13). Whether the removal is completed or not can be determined by whether or not the remaining film thickness at the removal point is a predetermined value or below.

In a case where the removal is not completed (in a case where step S13 is no), the process returns to step S11. In a case where the removal is completed (in a case where step S13 is yes), it is determined whether or not there is other removal points on the collector mirror 59 (step S14). In a case where there is another removal point (in a case where step S14 is yes), the low temperature medium spraying unit 62 and the gathering unit 63 are moved to the next removal point (step S15), the process is returned to step S11, and the removal processing is performed at the next removal point. In a case where there is no other removal point (in a case where step S14 is no), the cleaning processing ends.

In the first embodiment, the low temperature solid medium having the temperature lower than the phase transition temperature of the Sn is sprayed on the collector mirror 59. Accordingly, the βSn 591 adhered to the surface of the collector mirror 59 undergoes the phase transition to the αSn 592 having the fragile characteristic. Furthermore, there is an effect that the αSn 592, which has become fragile, is desorbed by the shock of the low temperature solid medium colliding into the collector mirror 59, whereby the surface of the collector mirror 59 can be cleaned.

A sublimable material is used as the low temperature solid medium, whereby there is almost no concern of contaminating the inside of the vacuum chamber 51. Even if the low temperature solid medium is dropped to the bottom face of the vacuum chamber 51, it vaporizes with lapse of time, whereby it is evacuated to outside of the vacuum chamber 51 by an evacuation means. Furthermore, in a case where the dry ice is used as the low temperature solid medium, a vaporized gas is carbon dioxide, which is neither an explosive or poisonous gas. Therefore, it is possible that it is not necessary to conduct a strict control of evacuation processing unlike in a case where the explosive or poisonous gas is used. Furthermore, the collector mirror 59 is cooled within the temperature range in which the collector mirror 59 is elastically deformed. Accordingly, it is possible that no unresolvable thermal distortion is added to the collector mirror 59.

Note that in the EUV exposure apparatus 1, in a case where the contaminated collector mirror 59 is not cleaned but is replaced instead, it is necessary to open the vacuum chamber 51 to the atmosphere. In this case, after the vacuum chamber 51 is opened to the atmosphere and the collector mirror 59 is replaced, the inside of the vacuum chamber 51 is evacuated again to the predetermined degree of vacuum so as to realize a stable state in the vacuum chamber 51. This processing takes about one day. That is, the EUV exposure apparatus 1 cannot be used for about one day. On the other hand, in the cleaning method according to the first embodiment, the vacuum chamber 51 is not opened to the atmosphere. Therefore, the cleaning processing can be completed in a relatively short time compared to the case where the collector mirror 59 is replaced. That is, it is possible that loss of operation time of the EUV exposure apparatus 1 can be decreased compared to the case where the collector mirror 59 is replaced.

### Second Embodiment

In the step of gathering in the first embodiment, a case where a low temperature solid medium is sprayed on a collector mirror has been described. In a second embodiment, a case where a low temperature gas medium is sprayed on the collector mirror for cleaning is described.

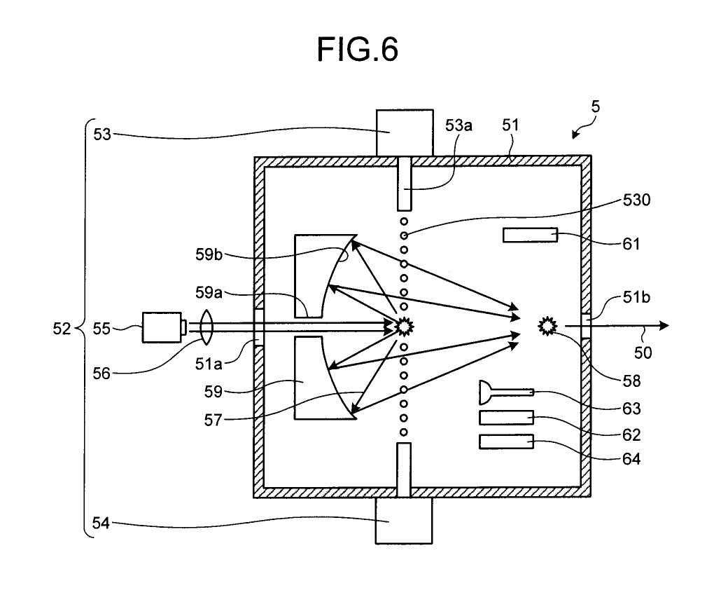

FIG. 6 is a view illustrating one example of a configuration of a light source according to the second embodiment. In the second embodiment, in addition to the configuration in FIG. 2, there is further provided a medium spraying unit 64 configured to spray a medium that desorbs βSn, which has become fragile, from a surface of the collector mirror 59. Furthermore, there is a difference from the first embodiment in that the low temperature medium spraying unit 62 sprays a low temperature gas medium instead of the low temperature solid medium. As the low temperature gas medium, a gas at a phase transition temperature of the βSn or below is used.

The medium spraying unit 64 sprays the gaseous body to the surface of the collector mirror 59 to which αSn that has undergone phase transition is adhered. It has a function to desorb the αSn from the surface of the collector mirror 59 by shock of the gaseous body hitting the surface of the collector mirror 59. Unlike the low temperature medium, it is not necessary that the gaseous body have a temperature equal to or lower than the phase transition temperature of the βSn. As a type of the gaseous body, it is desirable that the gaseous body have no influence on the vacuum chamber 51 and on a member inside of the vacuum chamber 51. For example, it is desirable that the gaseous body be an inert gas having low chemical reactivity such as He, Ar, and N₂. Note that it is also possible to use an active gas by making the vacuum chamber 51 and the member inside of the vacuum chamber 51 highly durable, by detoxifying the evacuation, and the like. The medium spraying unit 64 is also arranged to the storage position during exposure processing and is moved to the operating position during cleaning processing. Note that the same constituent element as the first embodiment is denoted with the same reference numeral, and a description thereof is omitted.

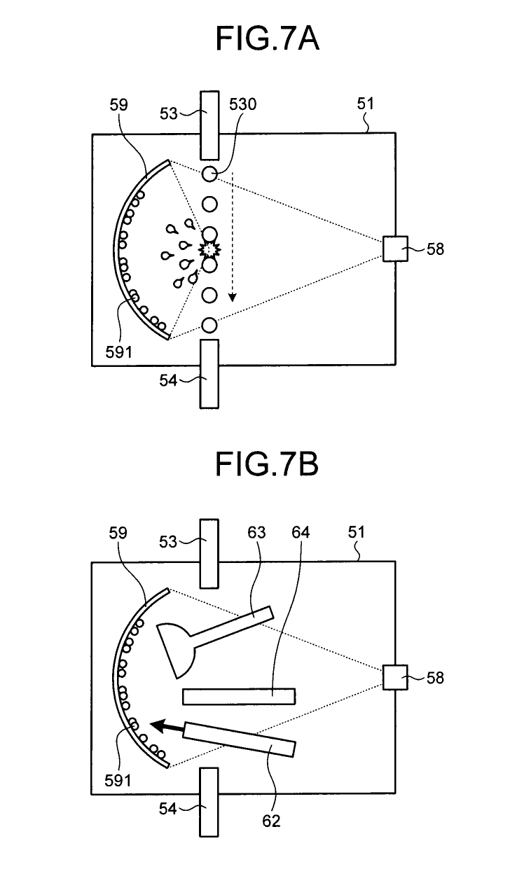

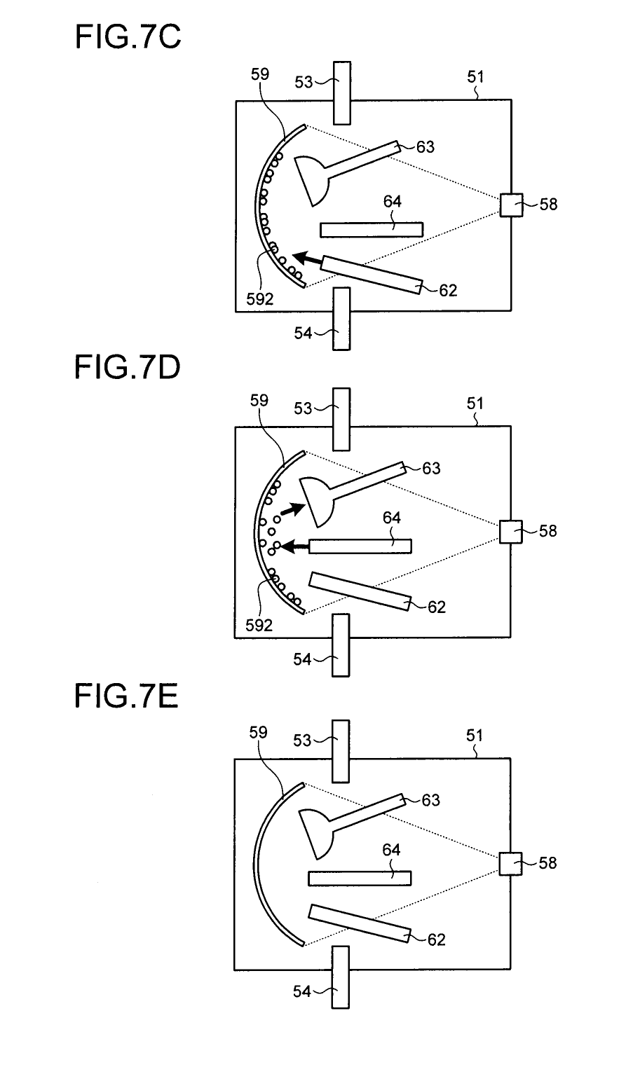

FIGS. 7A to 7E are views schematically illustrating one example of a procedure of a cleaning method of a light source according to the second embodiment. For example, as illustrated in FIG. 7A, the βSn 591, which is stable at a normal temperature, is deposited on the surface of the collector mirror 59 during the exposure processing. The cleaning processing is executed when it is determined by the surface condition detection unit 61 that the cleaning of the collector mirror 59 is necessary. Thereupon, as illustrated in FIG. 7B, the low temperature medium spraying unit 62, the gathering unit 63, and the medium spraying unit 64 are moved from the storage position to the operating position by a moving mechanism, which is not illustrated. Then, in this state, the low temperature gas medium is sprayed on the surface of the collector mirror 59 from the low temperature medium spraying unit 62. Due to spraying of the low temperature gas medium, a temperature of the βSn 591 is decreased, whereby it is cooled to the phase transition temperature or below. Accordingly, as illustrated in FIG. 7C, phase transition to the αSn 592 having a fragile characteristic takes place.

Next, as illustrated in FIG. 7D, spray processing of the low temperature medium by the low temperature medium spraying unit 62 is completed, and the inert gas is sprayed from the medium spraying unit 64 on a region, in which the βSn 591 has undergone the phase transition to the αSn 592, of the collector mirror 59. By shock caused by the inert gas colliding into the collector mirror 59, the αSn 592, which has become fragile, is desorbed. Then, the desorbed αSn 592 is gathered by the gathering unit 63, which is arranged close to the medium spraying unit 64. Note that it is possible to decrease temperature of the entire collector mirror 59 and gather the αSn 592 from the entire collector mirror 59, or it is possible to decrease temperature of a region of the collector mirror 59, and after the αSn 592 in the region has been gathered, to perform the same processing in another region of the collector mirror 59.

Next, as illustrated in FIG. 7E, when the αSn 592 on the surface of the collector mirror 59 is removed, an end point of the cleaning is detected by the surface condition detection unit 61. Then, the low temperature medium spraying unit 62, the gathering unit 63, and the medium spraying unit 64 are moved from the operating position to the storage position. Subsequently, the low temperature medium and the inert gas inside of the vacuum chamber 51 are evacuated, and evacuation is performed until the inside of the vacuum chamber 51 reaches a predetermined pressure.

It is possible to obtain the same effect as the first embodiment by using the second embodiment.

### Third Embodiment

In the first and the second embodiments, the temperature of the collector mirror is decreased to the phase transition temperature of the βSn or below by spraying the low temperature medium on the surface of the collector mirror. In a third embodiment, a case is described in which the temperature of the collector mirror is decreased to the phase transition temperature of the βSn or below by flowing a refrigerant in the collector mirror.

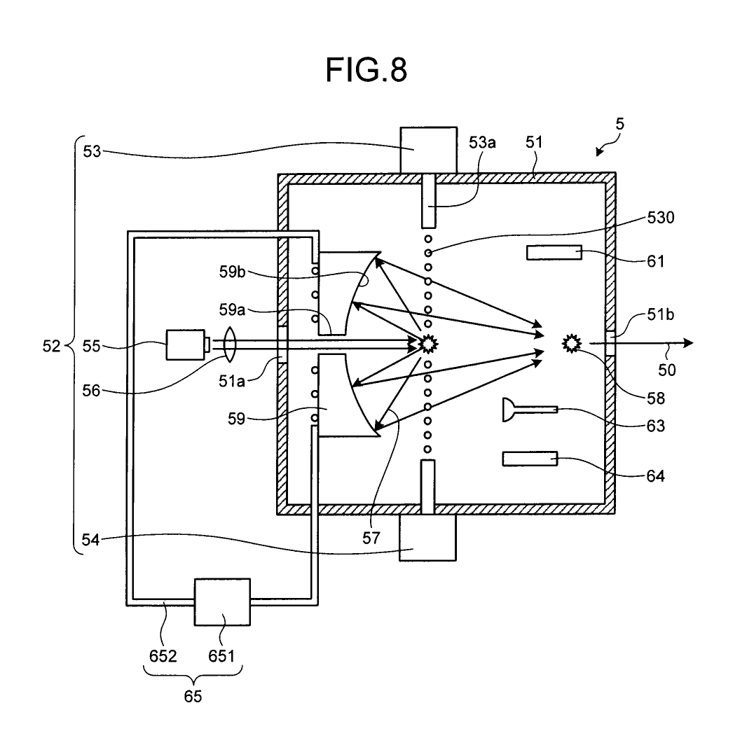

FIG. 8 is a view illustrating one example of a configuration of a light source according to the third embodiment. In the third embodiment, the low temperature medium spraying unit 62 is removed from the configuration in FIG. 6 of the second embodiment, and there is further provided a collector mirror cooling unit 65. The collector mirror cooling unit 65 is provided with a refrigerant supply unit 651 and a piping 652. The refrigerant supply unit 651 supplies a refrigerant at a temperature of the phase transition temperature of the βSn or below to the collector mirror 59. As the refrigerant, alcohol such as ethanol and methanol may be used. The piping 652 is arranged so as to pass through the inside of the collector mirror 59 or to abut on the collector mirror 59, and is connected to the refrigerant supply unit 651. With this structure, the refrigerant is supplied from the refrigerant supply unit 651 to the collector mirror 59 through the piping 652, whereby it is possible to decrease the temperature of the collector mirror 59. In this case, a temperature of the refrigerant is to be within a temperature range in which thermal distortion of the collector mirror 59 is within an elastic deformation region of the collector mirror 59. Note, however, that any other configuration is the same as that of the first and the second embodiments, whereby a description thereof is omitted.

Furthermore, a cleaning method according to the third embodiment is substantially the same as the cleaning method according to the second embodiment, whereby a description thereof is omitted. Note, however, that the third embodiment is different from the second embodiment in that the temperature of the collector mirror 59 is not lowered by spraying the low temperature medium from the low temperature medium spraying unit 62, but the temperature of the collector mirror 59 is lowered through cooling by using the refrigerant flowing through the piping 652 of the collector mirror cooling unit 65.

It is possible to obtain the same effect as the first embodiment by using the third embodiment.

Note that in the descriptions according to the first to the third embodiments, the time to perform cleaning and the time to end the cleaning are detected by the surface condition detection unit 61. However, if it is possible to acquire distribution of reflectance of the collector mirror 59 during exposure processing, the time to perform the cleaning may be determined by using the distribution of reflectance. Furthermore, by obtaining operating time, after which it is better to clean the collector mirror 59, of the EUV exposure apparatus 1 through an experiment in advance, it is also possible to perform the cleaning once the operating time of the EUV exposure apparatus 1 has passed. Furthermore, in a case where the hours, within which Sn adhered to the surface of the collector mirror 59 can be surely removed, are known through an experiment and the like, it is also possible to perform spray processing for a predetermined period of time without detecting an end point of the cleaning by the surface condition detection unit 61. In this way, the surface condition detection unit 61 may not be provided in a case where it is possible to determine the time to execute the cleaning and the time to end the cleaning.

It is an objective of the gathering unit 63 to remove the Sn remaining inside of the vacuum chamber 51 to outside of the vacuum chamber 51. However, as long as the αSn desorbed by the low temperature medium spraying unit 62 is dropped to a bottom of the vacuum chamber 51, there is no serious influence on generation of EUV light. Therefore, the gathering unit 63 may not be provided.

Furthermore, in the above-described description, the cleaning by the light source 5 of the EUV exposure apparatus 1 has been exemplified; however, it is not to be limited to this. For example, there is a case where a resist is evaporated during the exposure processing in a conventional exposure apparatus and is adhered to an optical system such as a transmission type lens or a mirror. The above-described embodiments are applicable to such removal of the resist adhered to the optical system. More specifically, the above-described embodiments are applicable to a case where an adhered substance is adhered to an optical component in an optical apparatus, which is a target of the removal, and there is a difference between a coefficient of thermal expansion of the optical component and a coefficient of thermal expansion of the adhered substance. When there is a difference in the coefficients of thermal expansion, by cooling, stress is generated and a crack is caused in the adhered substance, whereby it is easily peeled off. And the temperature of the process is desired to be in the range of the elastic domain of those components.

Furthermore, in the above-described descriptions, a window 51b is provided in a portion of the vacuum chamber 51 to be an interface with the illumination optical system 7. It is also possible to provide a gate valve instead of the window 51b. In this case, the gate valve is opened in a case where lithography processing is performed, and the gate valve is closed in a case where cleaning processing is performed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A cleaning apparatus of an optical apparatus comprising a first medium spraying unit configured to spray a medium to an adhered substance adhered to an optical component, the medium being cooled to a temperature lower than a room temperature and changing a state of the adhered substance into a fragile state.

2. The cleaning apparatus of the optical apparatus according to claim 1, wherein the first medium spraying unit desorbs the adhered substance changed into the fragile state from the optical component.

3. The cleaning apparatus of the optical apparatus according to claim 2, wherein the medium is a sublimable solid.

4. The cleaning apparatus of the optical apparatus according to claim 1, wherein the medium has a temperature equal to or lower than a phase transition temperature of the adhered substance.

5. The cleaning apparatus of the optical apparatus according to claim 2, wherein the first medium spraying unit performs cooling of the adhered substance as well as desorption of the adhered substance for each predetermined region.

6. The cleaning apparatus of the optical apparatus according to claim 2, wherein the first medium spraying unit performs cooling of the adhered substance as well as desorption of the adhered substance in a part of or on an entire surface of the optical component.

7. The cleaning apparatus of the optical apparatus according to claim 1, further comprising a second medium spraying unit configured to spray a medium for removal, which desorbs the adhered substance cooled by the first medium spraying unit, on the optical component, wherein
the medium for removal is a gas.

8. The cleaning apparatus of the optical apparatus according to claim 1, further comprising a gathering unit configured to gather the adhered substance desorbed from the optical component.

9. The cleaning apparatus of the optical apparatus according to claim 1, further comprising a surface condition detection unit configured to measure thickness or an amount of adhesion of the adhered substance adhered to a surface of the optical component.

10. A cleaning apparatus of an optical apparatus comprising:
a refrigerant supply unit configured to supply a refrigerant having a temperature lower than a room temperature to a piping arranged so as to abut on or pass through an optical component having a surface to which an adhered substance is adhered; and
a medium spraying unit configured to spray a medium for removal, which is cooled in the refrigerant supply unit and desorbs the adhered substance on the optical component.

11. The cleaning apparatus of the optical apparatus according to claim 10, further comprising a gathering unit configured to gather the adhered substance desorbed from the optical component.

12. The cleaning apparatus of the optical apparatus according to claim 10, further comprising a surface condition detection unit configured to measure thickness or an amount of adhesion of the adhered substance adhered to a surface of the optical component.

13. An optical apparatus comprising:
an optical component;
a first medium spraying unit configured to spray a medium to an adhered substance adhered to the optical component, the medium being cooled to a temperature lower than a room temperature and changing a state of the adhered substance into a fragile state.

14. The optical apparatus according to claim 13, wherein the first medium spraying unit desorbs the adhered substance changed into the fragile state from the optical component.

15. The optical apparatus according to claim 14, wherein the medium is a sublimable solid.

16. The optical apparatus according to claim 13, wherein the medium has a temperature equal to or lower than a phase transition temperature of the adhered substance.

17. The optical apparatus according to claim 13, further comprising a second medium spraying unit configured to spray a medium for removal, which desorbs the adhered substance cooled by the first medium spraying unit, on the optical component, wherein
the medium for removal is a gas.

18. The optical apparatus according to claim 13, further comprising a gathering unit configured to gather the adhered substance desorbed from the optical component.

19. The optical apparatus according to claim 13, further comprising a surface condition detection unit configured to measure thickness or an amount of adhesion of the adhered substance adhered to a surface of the optical component.

20. An exposure apparatus comprising:
a vacuum chamber;
a liquid droplet supply unit configured to supply a Sn droplet to the vacuum chamber;
a laser oscillator configured to oscillate a laser, with which the Sn droplet dropped from the liquid droplet supply unit is to be irradiated;
a collector mirror configured to condense EUV light emitted from the Sn droplet being irradiated with the laser and being excited; and
the cleaning apparatus of the optical apparatus according to claim 1.
